(19) United States
(12) Patent Application Publication
(10) Pub. No.: US 2022/0234957 A1
(43) Pub. Date: Jul. 28, 2022

(54) CERAMIC STRUCTURE AND SUPPORTING MECHANISM WHICH IS PROVIDED WITH SAID CERAMIC STRUCTURE

(71) Applicant: KYOCERA Corporation, Kyoto-shi, Kyoto (JP)

(72) Inventors: Yukio NOGUCHI, Koka-shi, Shiga (JP); Kouji TERAMOTO, Koka-shi, Shiga (JP)

(21) Appl. No.: 17/434,701

(22) PCT Filed: Feb. 27, 2020
(86) PCT No.: PCT/JP2020/008128

§ 371 Date: Apr. 6, 2022

(30) Foreign Application Priority Data
Mar. 1, 2019 (JP) 2019-037492

(51) Int. Cl. C04B 35/44; C04B 37/00

(52) U.S. Cl. CPC C04B 35/44; C04B 37/00; C04B 2237/76; C04B 2235/3222; C04B 2237/343; C04B 2235/3225

(57) ABSTRACT

A ceramic structure of the present disclosure is provided with: a first member made of a single crystal of sapphire or an yttrium aluminum composite oxide; and a second member in contact with the first member, the second member being made of ceramic containing an aluminum oxide or an yttrium aluminum composite oxide as a principal component, wherein, of crystal grains constituting the second member, contact grains of the second member, which are grains in contact with the first member, include a first curved surface part that is convex toward the first member.

### TECHNICAL FIELD

The present disclosure relates to a ceramic structure and a support mechanism provided with the ceramic structure.

### BACKGROUND ART

A shower plate made of ceramic is used to supply gas fed into a semiconductor manufacturing device toward a semiconductor substrate. When the outer peripheral side of the shower plate is directly fixed to a support member made of metal, the manufacturing process is complicated, and the cost is likely to increase. Furthermore, there is a problem that the shower plate is easily damaged by thermal stress due to a difference in the linear expansion coefficients of the shower plate and the support member.

To solve such problems, Patent Document 1 proposes a showerhead in which a shower plate made of ceramic and a support member made of metal are mechanically fixed with a plurality of springs. Patent Document 1 describes that the material of the spring is a metal, such as a nickel alloy, an aluminum alloy, or a stainless steel.

In addition, Patent Document 2 proposes a component assembly in which a gas distribution plate (shower plate) and a support member are bonded with a sheet-shaped elastomer adhesive to relieve thermal stress.

### PRIOR ART DOCUMENTS

### Patent Documents

Patent Document 1: JP 2008-290417 A

Patent Document 2: JP 2011-508419 T

### SUMMARY OF THE INVENTION

A ceramic structure of the present disclosure is provided with:

a first member made of a single crystal of sapphire or an yttrium aluminum composite oxide; and

a second member in contact with the first member, the second member being made of ceramic containing an aluminum oxide as a principal component,

wherein, of crystal grains constituting the second member, contact grains of the second member in contact with the first member include a first curved surface part that is convex toward the first member.

A support mechanism of the present disclosure is provided with the ceramic structure described above, wherein

the first member is a disk-shaped member provided with a plurality of through holes in the thickness direction, and the second member is an annular support member supporting an outer peripheral part of the first member;

the first member includes a first surface and a second surface facing each other in the thickness direction; and

the second member is in contact with at least one of the first surface and the second surface.

### BRIEF DESCRIPTION OF DRAWINGS

FIG. 1(a) is a perspective view illustrating an example of a ceramic structure of the present disclosure, and (b) is a cross-sectional view taken along line A-A′ of (a).

FIG. 2 is an electron micrograph illustrating a part of a cross section of a portion where a first member and a second member in the ceramic structure illustrated in FIG. 1 are in contact with each other.

FIG. 3(a) is a perspective view illustrating an example of a support mechanism provided with the ceramic structure of the present disclosure, and (b) is a cross-sectional view taken along line B-B′ of (a).

FIG. 4(a) is a perspective view illustrating another example of a support mechanism provided with the ceramic structure of the present disclosure, and (b) is a cross-sectional view taken along line C-C′ of (a).

FIG. 5(a) is a perspective view illustrating another example of a support mechanism provided with the ceramic structure of the present disclosure, and (b) is a cross-sectional view taken along line D-D′ of (a).

FIG. 6(a) is a perspective view illustrating another example of a support mechanism provided with the ceramic structure of the present disclosure, (b) is a cross-sectional view taken along line E-E′ of (a), and (c) is an enlarged cross-sectional view of section F of (b).

FIG. 7(a) is a perspective view illustrating another example of a support mechanism provided with the ceramic structure of the present disclosure, (b) is a cross-sectional view taken along line G-G′ of (a), and (c) is an enlarged cross-sectional view of section M of (b).

### EMBODIMENTS FOR CARRYING OUT THE INVENTION

Hereinafter, embodiments of the present disclosure will be described in detail with reference to the drawings. However, in all figures of the present specification, the same portions are assigned the same reference numerals, and the descriptions are omitted at appropriate times unless confusion is caused.

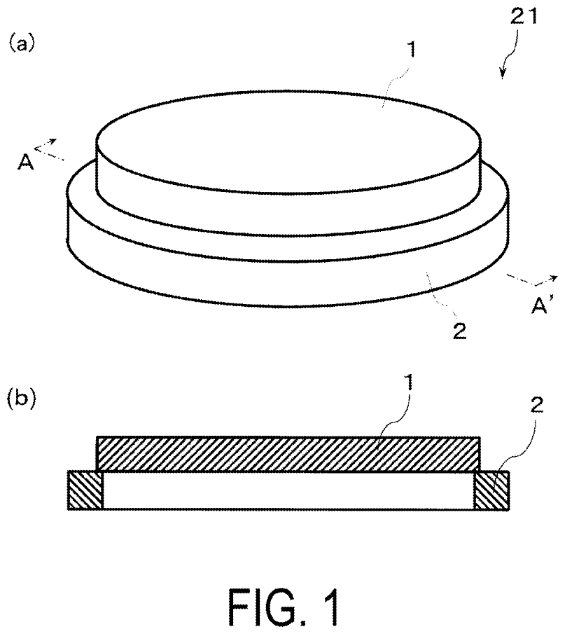

FIG. 1 illustrates an example of a ceramic structure of the present disclosure, where (a) is a perspective view and (b) is a cross-sectional view taken along line A-A′.

A ceramic structure 21 illustrated in FIG. 1 is provided with:

a first member 1 made of a single crystal of sapphire or an yttrium aluminum composite oxide; and

a second member 2 in contact with the first member 1, the second member 2 being made of ceramic containing an aluminum oxide or an yttrium aluminum composite as a principal component. For example, the first member 1 has a substrate shape, and the second member 2 has a substrate shape or an annular shape (the example illustrated in FIG. 1 depicts an annular shape). The ceramic structure 21 can be used as a semiconductor manufacturing member.

Here, the “principal component” in the present disclosure refers to the most predominant component in a total amount of 100 mass % of all components constituting the ceramic and is, in particular, contained in 70 mass % or higher and more preferably in 90 mass % or higher. The identification of each component is performed with an X-ray diffractometer using a CuKα beam, and the content of each component is determined, for example, with an inductively coupled plasma (ICP) emission spectrophotometer or an X-ray fluorescence spectrometer.

The first member 1 may contain an unavoidable impurity, for example, Si, Na, Mg, Cu, Fe, or Ca, each in 10 mass ppm or lower, and a total content of unavoidable impurities in the first member is lower than a total content of unavoidable impurities in the second member.

The second member 2 containing an aluminum oxide as a principal component is made of ceramic containing, for example, magnesium, silicon, and calcium each in an oxide form. In this case, the second member contains, for example, magnesium in an amount from 0.2 mass % to 0.4 mass % as expressed in terms of its oxide (MgO), silicon in an amount from 0.03 mass % to 0.05 mass % as expressed in terms of its oxide (SiO₂), and calcium in an amount from 0.01 mass % to 0.03 mass % of calcium as expressed in terms of its oxide (CaO).

Alternatively, the second member 2 is made of ceramic containing a crystal of α-Al₂O₃ and a crystal of an yttrium aluminum composite oxide and may contain Al in an amount of 70 mass % or higher and 98 mass % or lower as expressed in terms of Al₂O₃ and Y in an amount of 2 mass % or higher and 30 mass % or lower as expressed in terms of Y₂O₃. The second member containing an yttrium aluminum composite oxide as a principal component may contain a total of 3000 mass ppm of unavoidable impurities, for example, Si, Ca, Cr, Ni, K, Mg, and Fe.

The yttrium aluminum composite oxide is, for example, at least one of YAG, YAP, or YAM.

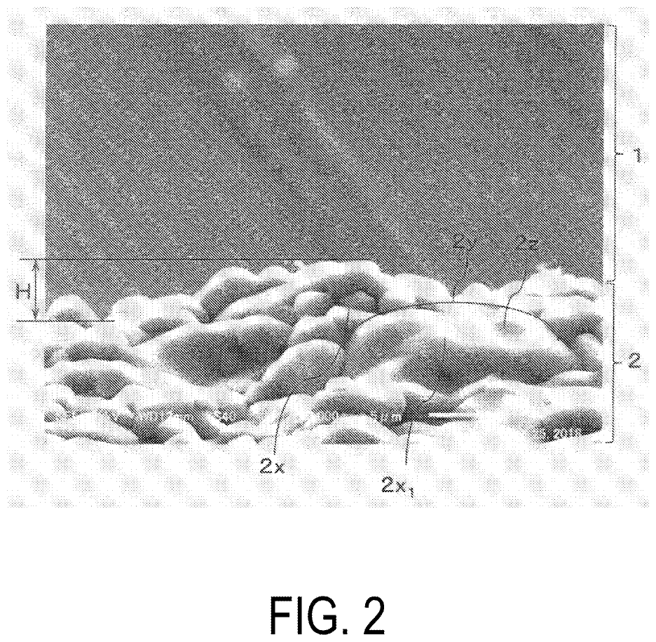

FIG. 2 is an electron micrograph illustrating a part of a cross section of a portion where the first member 1 and the second member 2 in the ceramic structure illustrated in FIG. 1 are in contact with each other (hereinafter, this part of the contact is referred to simply as the contact part). The electron micrograph illustrated in FIG. 2 depicts a cross section inclined to the contact surface to allow the grain boundaries of the crystal grains 2x constituting the second member 2 to be easily visible.

As illustrated in FIG. 2, of crystal grains 2x constituting the second member 2, contact grains 2x₁ of the second member in contact with the first member 1 include a first curved surface part 2y that is convex toward the first member 1.

Such a configuration increases an anchor effect of the contact grains 2x₁ of the second member 2 to the first member 1, and a metal or an organic component becomes less likely to be present between the first member 1 and the second member 2. Thus, this can reduce the risk of generation of particles or gas of these components. In addition, such a configuration improves air tightness in the contact part.

At least some of the contact grains 2x₁ may include a concave second curved surface part 2z in the convex first curved surface part 2y.

Such a configuration further increases the anchor effect and thus can further reduce the risk of generation of particles or gas of a metal or an organic component.

The contact grains 2x₁ in the ceramic structure 21 may have an average crystal grain size of 5 μm or greater and 10 μm or less.

With the average crystal grain size of 5 μm or greater, grain boundary phases bonding the crystal grains together do not extremely reduce, and thus the crystal grains are less susceptible to plucking out even though the grain boundary phases slightly corrode. In addition, plastic deformation at high temperatures is reduced. On the other hand, with the average crystal grain size of 10 μm or less, breakage toughness, rigidity, and mechanical strength can be increased.

The crystal grain size of the contact grains 2x₁ can be measured using the intercept method. Specifically, first, a cross section of a portion of the ceramic structure containing the contact grains 2x₁ is polished to form a mirror surface. The average crystal grain size can then be determined using a scanning electron microscope with a magnification factor of 3000 times by setting an observation range, for example, with a horizontal length of 45 μm and a vertical length of 34 μm in the mirror surface obtained by polishing, counting the number of grains crossing a straight line with a length of, for example, 20 μm, and dividing the length of the straight line by the number of the grains.

A height difference between an apex and a bottom of a plurality of the contact grains 2x₁ may be 15 μm or less. With the height difference H in this range, stress becomes less likely to remain even upon repeated heating and cooling, and thus this can reduce stress concentration in the vicinity of the contact part.

The height difference H is measured for the observation range described above. In the electron micrograph illustrated in FIG. 2, the height difference H is 4.8 μm.

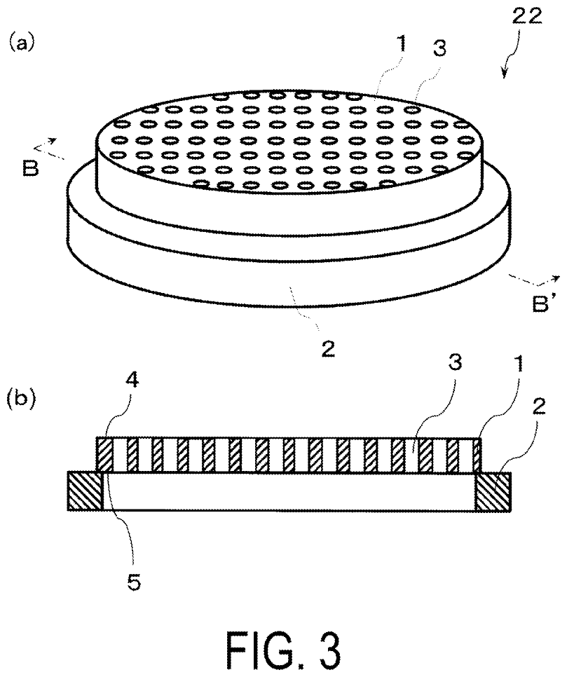

FIG. 3 illustrates an example of a support mechanism provided with the ceramic structure of the present disclosure, where (a) is a perspective view and (b) is a cross-sectional view taken along line B-B′.

The support mechanism 22 illustrated in FIG. 3 is a disk-shaped member in which the first member 1 is provided with a plurality of through holes 3 in the thickness direction, and the second member 2 is an annular support member supporting an outer peripheral part of the first member 1. The second member 2 is in contact with at least one of a first surface 4 and a second surface 5 facing each other in the thickness direction of the first member 1 (in the example illustrated in FIG. 3, the second surface 5 is in contact). The first member 1 is, for example, a shower plate in which a plasma-generating gas passes through the through holes 3 and is used in a thin film forming apparatus (e.g., a CVD apparatus) or an etching apparatus (e.g., a plasma etching apparatus) used in manufacturing processes of semiconductor devices.

For example, the first member 1 illustrated in FIGS. 1 and 3 has an outer diameter of 250 mm to 400 mm and a thickness of 3 mm to 10 mm, and the second member 2 has an outer diameter of 300 mm to 450 mm and a thickness of 3 mm to 10 mm.

The plasma-generating gas is, for example, a fluorine-based gas, such as SF₆, CF₄, CHF₃, ClF₃, NF₃, C₄F₈, or HF; or a chlorine-based gas, such as Cl₂, HCl, BCl₃, or CCl₄.

In the support mechanism 22 thus configured, a metal or an organic component is not present between the first member 1 and the second member 2, and thus particles or gas of these components will not pollute the inside of a semiconductor manufacturing device. In addition, the linear expansion coefficients of the first member 1 and the second member 2 are almost the same, and thus a crack is less likely to occur even upon repeated heating and cooling.

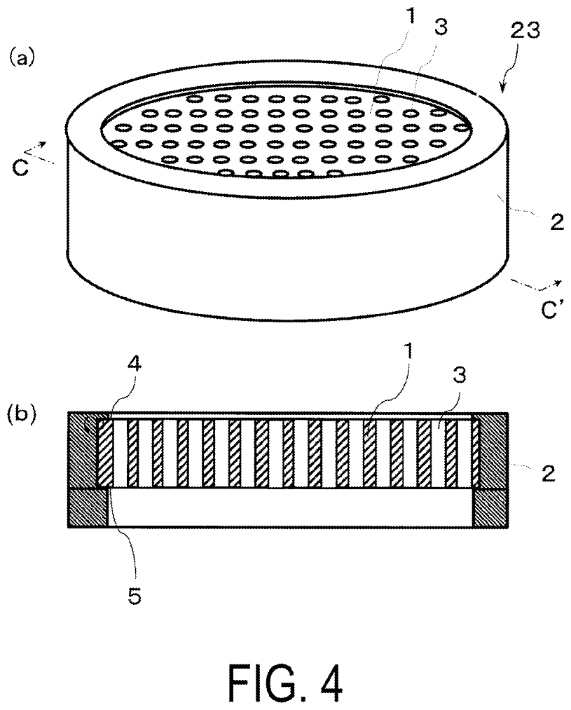

FIG. 4 illustrates another example of a support mechanism provided with the ceramic structure of the present disclosure, where (a) is a perspective view and (b) is a cross-sectional view taken along line C-C′.

In the support mechanism 23 illustrated in FIG. 4, the second member 2 holds the first member 1 from both sides of the first surface 4 and the second surface 5 of the first member 1.

In the support mechanism 23 thus configured, the first member 1 is fixed to the second member 2 with high reliability, and thus, the first member 1 is not easily detached from the second member 2 even when subjected to disturbance, such as vibration.

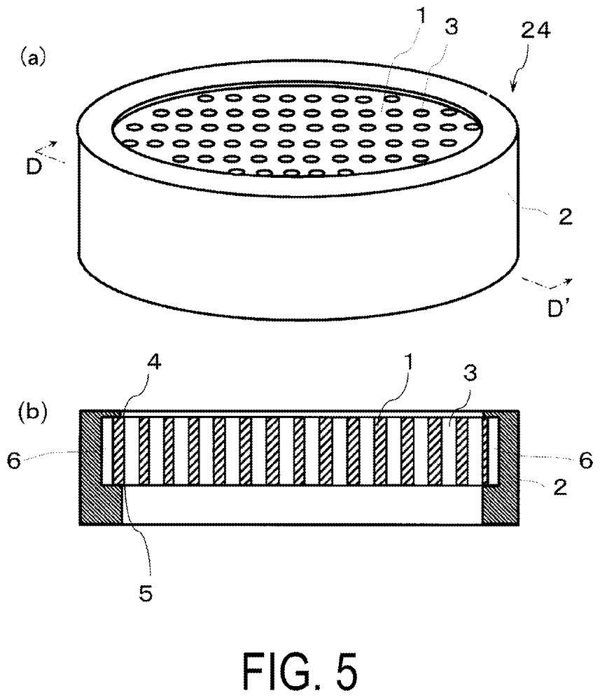

FIG. 5 illustrates another example of a support mechanism provided with the ceramic structure of the present disclosure, where (a) is a perspective view and (b) is a cross-sectional view taken along line D-D′.

The support mechanism 24 illustrated in FIG. 5 is provided with an annular space part 6 between the first member 1 and the second member 2, the annular space part being isolated from outside.

In the support mechanism 24 thus configured, the outer peripheral surface of the first member 1 is not restrained by the second member 2, and thus stress generated on the outer peripheral part of the first member 1 upon repeated heating and cooling becomes less likely to remain.

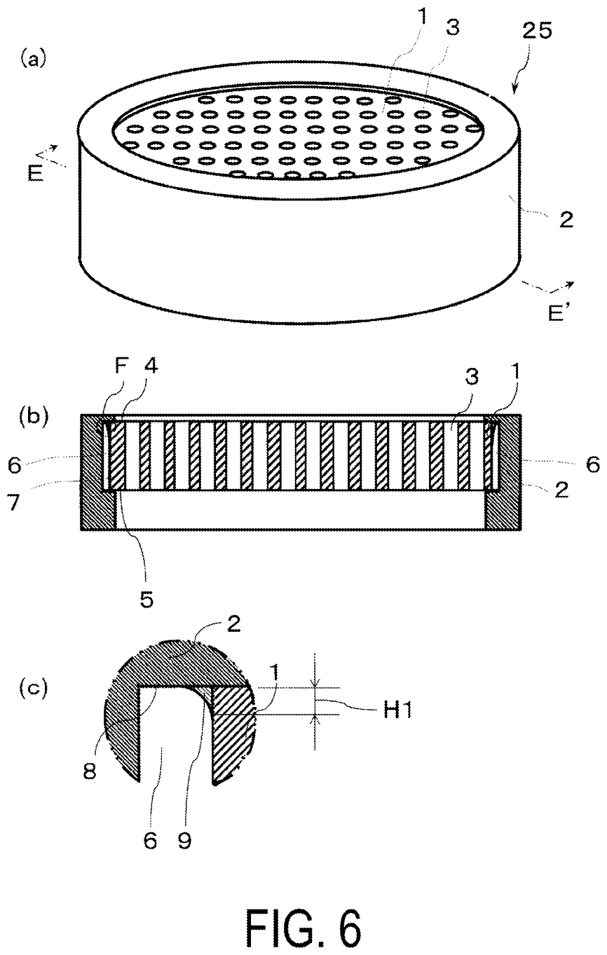

FIG. 6 illustrates another example of a support mechanism provided with the ceramic structure of the present disclosure, where (a) is a perspective view, (b) is a cross-sectional view taken along line E-E′, and (c) is an enlarged cross-sectional view of section F of (b).

The support mechanism 25 illustrated in FIG. 6 is provided with a first cover part 9 in the annular space part 6 from the outer peripheral surface 7 of the first member 1 to at least one of a third surface 8 of the second member 2 in contact with the first surface 4, and a fourth surface of the second member 2 facing the second surface 5 (the third surface 8 in the example illustrated in FIG. 6).

In the support mechanism 25 thus configured, the first cover part 9 prevents a metal or an organic component from entering between the first member 1 and the second member 2, and thus this can reduce the risk of generation of particles or gas of these components. In addition, such a configuration further improves air tightness in the contact part.

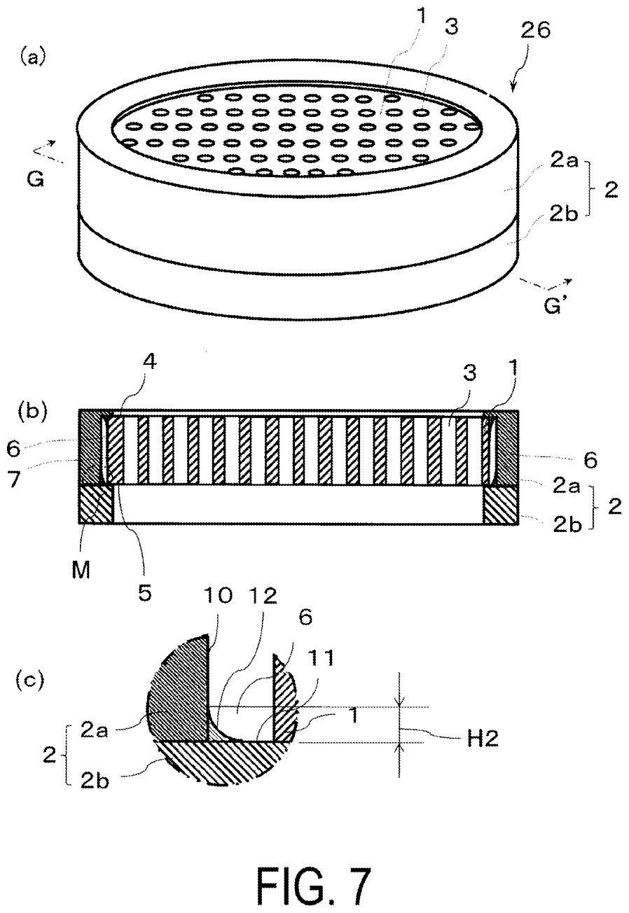

FIG. 7 illustrates another example of a support mechanism provided with the ceramic structure of the present disclosure, where (a) is a perspective view, (b) is a cross-sectional view taken along line G-G′, and (c) is an enlarged cross-sectional view of section M of (b).

In the support mechanism 26 illustrated in FIG. 7, the second member 2 is provided with a substrate 2b in contact with the second surface 5, and a frame body 2a located in a periphery of the first member 1 and including a recessed portion housing the first member 1; and the second member 2 includes a second cover part 12 from an inner peripheral surface 10 of the frame body 2a to a main surface 11 of the substrate 2b, the main surface 11 being located on the frame body 2a side.

In the support mechanism 26 thus configured, the second cover part 12 prevents a metal or an organic component from entering between the substrate 2b and the frame body 2a, and thus this can reduce the risk of generation of particles or gas of these components.

As illustrated in FIGS. 5 to 7, the first member 1 has an outer diameter of 250 mm to 400 mm and a thickness of 3 mm to 10 mm, and the second member 2 has an outer diameter of 300 mm to 450 mm and a thickness that is 3 to 6 mm greater than the thickness of the first member 1.

In addition, an average diameter of closed pores of at least one of the first cover part 9 and the second cover part 12 may be not less than 0.8 times and not greater than 1.5 times an average diameter of closed pores of the support member 2 (2a, 2b).

With the average diameter of closed pores of at least one of the first cover part 9 and the second cover part 12 in this range, closed pores that potentially cause breakage are small, and thus this can prevent breakage of the support mechanism originating from a closed pore present in at least one of the first cover part 9 and the second cover part 12 with an average diameter of closed pores in this range.

In addition, an average diameter of closed pores of at least one of the first cover part 9 and the second cover part 12 may be smaller than that of closed pores of the second member 2 (2a, 2b).

With the average diameter of closed pores of at least one of the first cover part 9 and the second cover part 12 in this range, closed pores that potentially cause breakage are small, and thus this can further enhance the effect of preventing breakage of the support mechanism originating from a closed pore present in at least one of the first cover part 9 and the second cover part 12 with an average diameter of closed pores in this range.

A maximum height H1 of the first cover part 9 directed from the outer peripheral surface 7 toward the outer peripheral direction of the second member 2 is, for example, 400 μm or greater and 650 μm or less.

A maximum height H2 of the second cover part 12 directed from the inner peripheral surface 10 toward the center direction of the first member 1 is, for example, 400 μm or greater and 650 μm or less.

In addition, the surface of at least one of the first cover part 9 and the second cover part 12 may be curved. The curved surface is less likely to cause stress concentration than an exposed surface including a corner portion and thus can maintain mechanical strength.

The average diameter of the closed pores of each of these members can be measured by the following method.

First, cross sections of the second member 2 (2a, 2b), the first cover part 9, and the second cover part 12 are polished to form mirror surfaces, and for the cross section of each member, a scanning electron microscope is used with a magnification factor of 500 times to set an observation range, for example, with a horizontal length of 256 μm and a vertical length of 192 μm.

The average diameter of closed pores can be determined by applying a technique of particle analysis of image analysis software “A-zo-kun (Ver 2.52)” (trade name, available from Asahi Kasei Engineering Corporation, hereinafter, described simply as the image analysis software) to this observation range. The average diameter of closed pores is the average value of the equivalent circle diameter.

In the analysis, conditions for the particle analysis are set as follows: the brightness of particles is set to dark, the binarization method to manual, the threshold value to 70 to 100, the small figure removal area to 0.3 μm², and the noise removal filter to available.

In the measurement described above, the threshold value is set to 70 to 100, but the threshold value is adjusted according to the brightness of the image of the observation range; the brightness of particles is set to dark, the binarization method to manual, the small figure removal area to 0.3 μm², and the noise removal filter to available, and then the threshold value is adjusted to allow a marker appearing in the image to match the shape of a closed pore.

Next, a method of manufacturing the ceramic structure of the present disclosure will be described.

For forming the second member with ceramic containing an aluminum oxide as a principal component, a mixed powder prepared by weighing to contain 0.3 mass % of magnesium hydroxide as expressed in terms of oxide (MgO), 0.04 mass % of silicon oxide, 0.02 mass % of calcium carbonate as expressed in terms of oxide (CaO), and an aluminum oxide as the remainder is fed together with a solvent, such as water, into a tumbling mill and mixed using ceramic balls made of an aluminum oxide with a purity of 99.5 mass % or higher and 99.99 mass % or lower.

For forming the second member with ceramic containing a crystal of α-Al₂O₃ and a crystal of an yttrium aluminum composite oxide, a powder of α-Al₂O₃ with a purity of 95 mass % or higher, a BET specific surface area of 1 to 9 m²/g as measured by the BET method, and a particle size of 0.1 μm to 1.2 μm and a powder of Y₂O₃ with a purity of 95 mass % or higher, preferably 99.5 mass % or higher, a particle size of 5 μm or less, and a BET specific surface area of 2 to 9 m²/g are used.

A mixed powder prepared by weighing to contain from 70 mass % to 98 mass % of a powder of α-Al₂O₃ and from 2 mass % to 30 mass % of a powder of Y₂O₃ is mixed in the same manner as described above.

Then, a compacting binder, such as a polyvinyl alcohol, a polyethylene glycol, or an acrylic resin, is added and then mixed and stirred to obtain a slurry.

Here, an amount of the compacting binder added is 2 parts by mass or greater and 10 parts by mass or less in total relative to 100 parts by mass of the mixed powder.

For the second member containing an yttrium aluminum composite oxide as a principal component, the above mixed powder is replaced with a powder made of an YAG, for example, with a purity of 99.9 mass % or higher to produce a slurry.

Then, granules produced by spray-drying the slurry using a spray dryer is obtained. These granules are compacted by the CIP method, for example, with a pressure of 80 MPa or higher and 100 MPa or lower to obtain a powder compact, and the powder compact is machined to obtain an annular precursor.

Next, a method of manufacturing a paste will be described.

To the powder made of the mixed powder or the YAG with a purity of 99.9 mass % or higher described in the method of manufacturing the precursor, a solvent, such as pure water, is added such that a volume ratio of the mixed powder to the solvent is 55 to 60:40 to 45, and the total of this solvent and the mixed powder is 100 parts by mass. 8 parts by mass or greater and 20 parts by mass or less of at least one of cellulose-based polysaccharides is added to 100 parts by mass of the mixture, and these are placed in a housing container in a stirring apparatus, mixed and stirred to obtain a paste.

Here, the cellulose-based polysaccharide is, for example, at least one of methyl cellulose, ethyl cellulose, ethyl methyl cellulose, hydroxymethyl cellulose, hydroxypropyl methyl cellulose, hydroxyethyl methyl cellulose, carboxymethyl cellulose, carboxymethyl ethyl cellulose, or carboxyethyl cellulose.

After a portion of the upper surface of the precursor which comes into contact with the lower surface of the first member made of sapphire is coated with the paste, the upper surface of the precursor and the lower surface of the first member are placed facing each other, and a pressure of, for example, 10 kPa or higher and 40 kPa or lower is applied to the precursor and the first member. A thickness of the paste after coating is, for example, 0.1 mm or greater and 2 mm or less.

Here, to obtain a ceramic structure with an average crystal grain size of the contact grains of 5 μm or greater and 10 μm or less, the average particle size of the powder after mixing is adjusted, for example, to 1.5 μm or greater and 5 μm or greater.

In addition, to obtain a ceramic structure with a height difference between the apex and the bottom of a plurality of the contact grains of 15 μm or less, the height difference of the thickness of the paste after coating is adjusted, for example, to 20 μm or less.

The paste is then dried by retaining the structure at ambient temperature for 12 hours or longer and 48 hours or shorter while humidity is adjusted. Thereafter, the structure is fired by retaining the structure at a temperature of 1500° C. or higher and 1700° C. or lower in atmospheric atmosphere for 5 hours or longer and 8 hours or shorter, and thereby the ceramic structure 21 illustrated in FIG. 1 can be obtained.

Here, to obtain a ceramic structure in which at least some of the contact grains include a concave second curved surface part in the convex first curved surface part, the structure is fired at a temperature of 1600° C. or higher and 1700° C. or lower for 5 hours or longer and 8 hours or shorter.

In addition, the first member that is any disk-shaped member provided with a plurality of through holes in the thickness direction can be used to obtain the support mechanism 22 illustrated in FIG. 3.

Furthermore, the support mechanism 23 illustrated in FIG. 4 can be obtained by applying the paste to a portion of the upper surface of the precursor that comes into contact with the lower surface of the first member, and to the outer peripheral surface of the first member, and then drying and firing the structure by the method described above.

Moreover, to obtain the support mechanisms 24 and 25 illustrated in FIGS. 5 and 6, the recessed portion to be formed into the annular space part after firing is provided in the precursor in advance. To obtain the first cover part illustrated in FIG. 6, a pressure of, for example, 20 kPa or higher and 40 kPa or lower is applied to the precursor and the first member. The paste leaking from between the precursor and the first member to outside forms the first cover part after firing.

Still more, to obtain the support mechanism 26 illustrated in FIG. 7, a first precursor to be formed into the substrate after firing and a second precursor to be formed into the frame body after filing are prepared in advance, the paste is applied to the lower surface of the second precursor and to the lower surface and the upper surface of the first member, and a pressure of, for example, 20 kPa or higher and 40 kPa or lower is applied to the first precursor, the second precursor, and the first member. The paste leaking from between the first precursor and the second precursor to outside forms the second cover part after firing.

To obtain a support mechanism with an average diameter of closed pores of the first cover part of not less than 0.8 times and not greater than 1.5 times an average diameter of closed pores of the second member, a paste obtained by setting a rotational frequency of a stirring apparatus to 1200 rpm or higher and 1600 rpm or lower and a rotation time to 5 minutes or longer and 15 minutes or shorter is favorably used.

For obtaining a support mechanism with an average diameter of closed pores of the second cover part of not less than 0.8 times and not greater than 1.5 times an average diameter of closed pores of the second member, the same method as described above is used.

In addition, to obtain a support mechanism with an average diameter of closed pores of the first cover part smaller than an average diameter of closed pores of the second member, the rotational frequency is increased to 1400 rpm or higher and 1600 rpm or lower, and the rotation time is set to 5 minutes or longer and 15 minutes or shorter.

Also for obtaining a support mechanism with an average diameter of closed pores of the second cover part smaller than an average diameter of closed pores of the second member, the same method as described above is used.

### EXPLANATION OF SIGNS

1 First member
2 Second member
2a: Frame body
2b: Substrate
2x: Crystal grain
2x₁: Contact grain
2y: First curved surface part
2z: Second curved surface part
3: Through hole
4: First surface
5: Second surface
6: Annular space part
7: Outer peripheral surface
8: Third surface
9: First cover part
10: Inner peripheral surface
11: Main surface
12: Second cover part
21: Ceramic structure
22 to 26: Support mechanism

1. A ceramic structure comprising:
a first member made of a single crystal of sapphire or an yttrium aluminum composite oxide; and
a second member in contact with the first member, the second member being made of ceramic containing an aluminum oxide or an yttrium aluminum composite oxide as a principal component, wherein,
of crystal grains constituting the second member, contact grains of the second member, which are grains in contact with the first member, comprise a first curved surface part that is convex toward the first member.

2. The ceramic structure according to claim 1, wherein at least some of the contact grains comprise a concave second curved surface part in the first curved surface part that is convex.

3. The ceramic structure according to claim 1 or 2, wherein the contact grains have an average crystal grain size of 5 μm or greater and 10 μm or less.

4. The ceramic structure according to any of claims 1 to 3, wherein a height difference between an apex and a bottom of a plurality of the contact grains is 15 μm or less.

5. A support mechanism comprising the ceramic structure described in any of claims 1 to 4, wherein
the first member is a disk-shaped member comprising a plurality of through holes in the thickness direction, and the second member is an annular support member supporting an outer peripheral part of the first member;
the first member comprises a first surface and a second surface facing each other in a thickness direction; and
the second member is in contact with at least one of the first surface and the second surface.

6. The support mechanism according to claim 5, wherein the second member holds the first member from both sides of the first surface and the second surface.

7. The support mechanism according to claim 6, comprising an annular space part between the first member and the second member, the annular space part being isolated from outside.

8. The support mechanism according to claim 7, comprising a first cover part in the annular space part from an outer peripheral surface of the first member to at least one of a third surface of the second member in contact with the first surface, and a fourth surface of the second member in contact with the second surface.

9. The support mechanism according to any of claims 6 to 8, wherein the second member comprises a substrate in contact with the first surface, and a frame body located in a periphery of the first member and comprising a recessed portion housing the first member; and the second member comprises a second cover part from an inner peripheral surface of the frame body to a main surface of the substrate located on the frame body side.

10. The support mechanism according to claim 9, wherein an average diameter of closed pores of at least one of the first cover part and the second cover part is not less than 0.8 times and not greater than 1.5 times an average diameter of closed pores of the second member.

11. The support mechanism according to claim 9 or 10, wherein an average diameter of closed pores of at least one of the first cover part and the second cover part is smaller than that of closed pores of the second member.
